(19) United States
(12) Patent Application Publication
(10) Pub. No.: US 2026/0113901 A1
(43) Pub. Date: Apr. 23, 2026

(54) BLADE SERVER POWER CONTROL SYSTEM AND METHOD, AND BLADE SERVER

(71) Applicant: SUZHOU METABRAIN INTELLIGENT TECHNOLOGY CO., LTD., Suzhou, Jiangsu (CN)

(72) Inventor: Lei ZHOU, Suzhou, Jiangsu (CN)

(21) Appl. No.: 19/115,756

(22) PCT Filed: Dec. 22, 2023
(86) PCT No.: PCT/CN2023/141186

§ 371 Date: Mar. 26, 2025

(30) Foreign Application Priority Data
Jun. 13, 2023 (CN) 202310699361.9

(51) Int. Cl. H05K 7/20; G06F 11/30

(52) U.S. Cl. CPC H05K 7/20836; G06F 11/3062; H05K 7/20254; H05K 7/20272; H05K 7/20281; H05K 7/20781

(57) ABSTRACT

The present application provides a power control system and method for a blade server, and a blade server. The system includes: multiple blade nodes; cold plates in thermal exchange with the blade nodes, the cold plates contain coolant; a liquid cooling module for circulating the coolant in each of the cold plates; multiple power supply units for supplying power to the multiple blade nodes and the liquid cooling module; and an overall management and control module, communicatively connected to each of the blade nodes, the liquid cooling module, and each of the power supply units, configured for monitoring power consumption of each of the blade nodes and the liquid cooling module, and distributing the power consumption evenly among the multiple power supply units.

### CROSS-REFERENCE TO RELATED APPLICATION

The present application claims priority to Chinese patent application No. 202310699361.9, entitled “POWER CONTROL SYSTEM AND METHOD FOR BLADE SERVER, AND BLADE SERVER”, filed on Jun. 13, 2023 before the China National Intellectual Property Administration, which is incorporated herein in its entirety by reference.

### TECHNICAL FIELD

This application relates to the field of servers, and in particular to a power control system and method for a blade server, as well as a blade server.

### BACKGROUND

A blade server is a type of server that allows multiple card-like server units to be installed within a standard-height rack-mounted chassis, achieving high availability and high density. Its main structure consists of a large chassis, inside which many blade nodes can be inserted. Each blade node is essentially a system motherboard. Compared to rack-mounted servers, blade servers save more space. However, the heat dissipation issue is more prominent, and often large and powerful fans are installed inside the chassis to provide cooling.

Currently, although traditional blade servers have introduced cold plate liquid cooling technology (which uses a working fluid as an intermediary for heat transfer to carry heat from hot spots to a distant location for cooling), this approach has the following drawbacks: It does not provide optimized adaptation for multi-blade node server systems, fails to achieve balanced power consumption of the entire machine's power supply units (PSUs), lacks power redundancy among multi-blade node servers, and also does not reasonably account for the power consumption of the cold plates in the load control of the power supply units. Therefore, significant improvements are urgently needed.

### SUMMARY

The present application provides a power control system and method for a blade server, and a blade server.

A first aspect of the present application provides a power control system for a blade server, including:
multiple blade nodes;
cold plates in thermal exchange with the blade nodes, the cold plates contain coolant;
a liquid cooling module for circulating the coolant in each of the cold plates;
multiple power supply units for supplying power to the multiple blade nodes and the liquid cooling module; and
an overall management and control module, communicatively connected to each of the blade nodes, the liquid cooling module, and each of the power supply units, configured for monitoring power consumption of each of the blade nodes and the liquid cooling module, and distributing the power consumption evenly among the multiple power supply units.

In some embodiments, the overall management and control module is configured for obtaining a first power consumption by acquiring a current value and a voltage value of each of the blade nodes.

In some embodiments, a first current sensor and a first voltage sensor are provided at an input end of the liquid cooling module, and the overall management and control module is configured for obtaining a second power consumption according to data collected by the first current sensor and the first voltage sensor.

In some embodiments, the overall management and control module is further configured for obtaining a third power consumption thereof during operations and a fourth power consumption of peripheral components of the blade server during operations.

In some embodiments, the overall management and control module is further configured for: calculating a sum of all the first power consumption, the second power consumption, the third power consumption, and the fourth power consumption to obtain a total power consumption; and using a ratio of the total power consumption to a number of power supply units currently in operation as an output power consumption of each of the power supply units.

In some embodiments, the overall management and control module is further configured for recalculating the total power consumption and the output power consumption of each of the power supply units in response to detecting an increase in the first power consumption of a certain blade node.

In some embodiments, the overall management and control module is further configured for, in response to detecting the increase in the first power consumption of a certain blade node, proportionally increasing the second power consumption of the liquid cooling module based on an increment of the first power consumption before recalculating the total power consumption and the output power consumption of each of the power supply units.

In some embodiments, the overall management and control module is further configured for controlling the liquid cooling module to increase a flow of coolant to the cold plate corresponding to the certain blade node based on the increment of the second power consumption of the liquid cooling module.

In some embodiments, the overall management and control module is further configured for recalculating the total power consumption and the output power consumption of each of the power supply units in response to detecting a decrease in the first power consumption of a certain blade node.

In some embodiments, the overall management and control module is further configured for, in response to detecting the decrease in the first power consumption of the certain blade node, proportionally decreasing the second power consumption of the liquid cooling module based on a decrement of the first power consumption before recalculating the total power consumption and the output power consumption of each of the power supply units.

In some embodiments, the overall management and control module is further configured for controlling the liquid cooling module to reduce a flow of coolant to the cold plate corresponding to the certain blade node based on the decrement of the second power consumption of the liquid cooling module.

In some embodiments, the overall management and control module is further configured for:

determining a coolant flow rate of the liquid cooling module according to the following formula:

$$μ = \frac{{\sum }_{n = 1}^{n} ( Pn ) + PL + PW + PC - {\sum }_{n = 1}^{n} ( PFn ) - σ}{ρ \cdot t \cdot Δ K \cdot c}$$

where μ represents the coolant flow rate, n represents the number of nodes, Pn represents the first power consumption, PL represents the second power consumption, PC represents the third power consumption, PW represents the fourth power consumption, PFn represents an useful work power consumption for actual operation of an n-th blade node, σ represents a heat dissipation loss of the liquid cooling module and the cold plates, ρ represents density of the coolant, t represents a preset regulation and monitoring time of the liquid cooling module, ΔK represents a temperature change of the coolant compared to the most recent regulation, c represents a specific heat capacity of the coolant;
adjusting the liquid cooling module to output the coolant at the determined coolant flow rate.

In some embodiments, the overall management and control module is further configured for, in response to a failure of a certain power supply unit, evenly distributing the total power consumption among remaining power supply units that have not failed.

In some embodiments, the multiple power supply units adopt a redundant power supply architecture, and the redundant power supply architecture includes at least one backup power supply unit.

In some embodiments, the overall management and control module is further configured for, in response to the failure of a certain power supply unit, replacing the power supply unit that is faulty with the backup power supply unit and evenly distributing the total power consumption among the remaining power supply units and the backup power supply unit that is in operation.

In some embodiments, each of the blade nodes includes a baseboard management controller, configured for acquiring the current value and the voltage value of the corresponding blade node and sending them to the overall management and control module.

In some embodiments, each of the blade nodes includes a second current sensor and a second voltage sensor, and the overall management and control module acquires the current value and voltage value of the corresponding blade node through the second current sensor and the second voltage sensor.

In some embodiments, the overall management and control module is further configured for adjusting an output voltage and an output current of each of the power supply units to be the same, so that the power consumption is evenly distributed among the multiple power supply units.

A second aspect of the present application provides a power control method for a blade server, including:
acquiring a first power consumption of each blade node;
acquiring a second power consumption of a liquid cooling module providing cooling for all blade nodes;
acquiring a third power consumption of an overall management and control module in operation and a fourth power consumption of peripheral components in operation of the blade server;
calculating a total power consumption based on the first power consumption, the second power consumption, the third power consumption, and the fourth power consumption; and
distributing the total power consumption among multiple power supply units evenly.

In some embodiments, the power control method further includes:
returning to the step of acquiring the first power consumption of each blade node in response to detecting an increase in the first power consumption of a certain blade node.

In some embodiments, before returning to the step of acquiring the first power consumption of each blade node, the method further includes:
proportionally increasing the second power consumption of the liquid cooling module based on an increment of the first power consumption.

In some embodiments, the step of proportionally increasing the second power consumption of the liquid cooling module based on the increment of the first power consumption further includes:
increasing, based on the increment of the second power consumption of the liquid cooling module, a flow of coolant to the cold plate corresponding to the certain blade node through the liquid cooling module.

In some embodiments, the power control method further includes:
returning to the step of acquiring the first power consumption of each blade node in response to detecting a decrease in the first power consumption of a certain blade node.

In some embodiments, before returning to the step of acquiring the first power consumption of each blade node, the method further includes:
proportionally decreasing the second power consumption of the liquid cooling module based on a decrement of the first power consumption.

In some embodiments, the step of proportionally decreasing the second power consumption of the liquid cooling module based on the decrement of the first power consumption further includes:
reducing, based on the decrement of the second power consumption of the liquid cooling module, a flow of coolant to the cold plate corresponding to the certain blade node through the liquid cooling module.

A third aspect of the present application provides a blade server, including the power control system for the blade server described above.

### BRIEF DESCRIPTION OF THE DRAWINGS

In order to more clearly illustrate the embodiments of the present application or the technical solutions in the related art, the accompanying drawings needed for the description of the embodiments or the related art will be briefly introduced below. It is apparent that the accompanying drawings in the following description are only some embodiments of the present application. For those of skilled in the art, other embodiments can be obtained based on these drawings without creative efforts.

FIG. 1 is a schematic structural diagram of a power control system for a blade server according to an embodiment of the present application;

FIG. 2 is a flowchart of a power control method for a blade server according to an embodiment of the present application;

FIG. 3 is a schematic diagram of working principle of an overall management and control module according to another embodiment of the present application;

FIG. 4 is a schematic diagram illustrating a dynamic regulation of PSU power balance by the overall management and control module according to another embodiment of the present application.

### DESCRIPTION OF REFERENCE SIGNS

100: Power control system for blade server;
101: Blade node;
102: Cold plate;
103: Liquid cooling module;
104: Power supply unit;
105: Overall management and control module.

### DETAILED DESCRIPTION OF THE EMBODIMENTS

To make the objectives, technical solutions, and advantages of this application clearer, this application will be described in detail with reference to the accompanying drawings and embodiments. It should be understood that the specific embodiments described here are used to explain the present application and are not intended to limit the present application.

It should be noted that all uses of “first” and “second” in the embodiments of this application are intended to distinguish between two entities or parameters with the same name but not identical. It is clear that “first” and “second” are used only for convenience of description and should not be construed as limiting the embodiments of this application. Subsequent embodiments will not repeat this explanation.

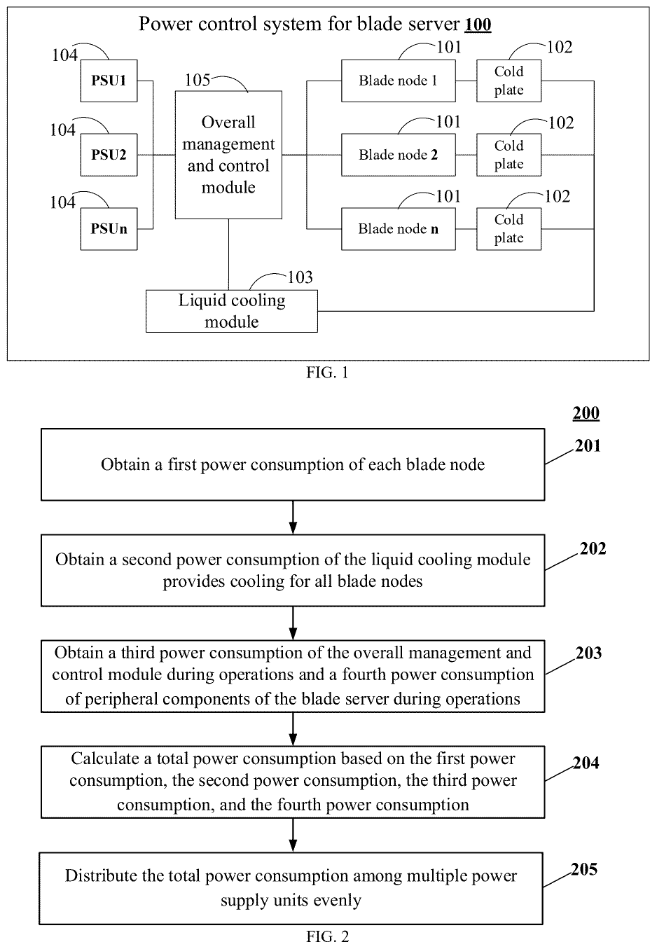

In an embodiment, as shown in FIG. 1, the present application provides a power control system 100 for a blade server. Specifically, the system includes multiple blade nodes 101, cold plates 102, a liquid cooling module 103, multiple power supply units 104 and an overall management and control module 105.

In this embodiment, each blade node 101 refers to a computing board used for providing computing power, such as offering network, data processing, image processing, storage, and other services. In specific implementations, the functions and configurations of different blade nodes can be the same or different. The multiple blade nodes 101 are inserted into a standard-height chassis (such as 1U, 2U, etc.), and these blade nodes are used to implement a low-cost server platform with high availability high density (HAHD) to handle high-density computing tasks. As shown in FIG. 1, there are n blade nodes 101, where n is a positive integer greater than or equal to two. In practice, the number of blade nodes 101 can be set according to business scenarios or user requirements. This application does not limit the specific number of blade nodes, which is used here only for illustrative purposes.

The cold plates 102 are in thermal exchange with each blade node 101, and contain coolant (not shown in the figure).

In this embodiment, each cold plate 102 is filled with liquid coolant, which uses a working fluid as an intermediary for heat transfer to carry heat from hot spots to a distant location for cooling. Both the cold plates 102 and the coolant in this application adopt existing cold plate liquid cooling technology.

The liquid cooling module 103 is configured for circulating the coolant within each cold plate 102.

In this embodiment, the liquid cooling module 103 can achieve the function of cooling the coolant, such as reducing the temperature of the coolant from a relatively high temperature to a preset relatively low temperature. The liquid cooling module 103 is usually located outside the heat dissipation area and can drive the coolant to circulate between the heat dissipation area and the non-heat dissipation area.

The multiple power supply units 104 are used for supplying power to the multiple blade nodes 101 and the liquid cooling module 103.

In this embodiment, the power supply unit 104, or PSU, is used for supplying power to the server, converts high-voltage alternating current into stable low-voltage direct current to supply various power-consuming components of the server, such as the motherboard, blade nodes, air-cooled heat dissipation devices, and the liquid cooling module.

The overall management and control module 105 is communicatively connected to each blade node 101, the liquid cooling module 103, and each power supply unit, and configured for monitoring the power consumption of each blade node 101 and the liquid cooling module 103, and distributing the power consumption evenly among multiple power supply units 104.

The power control system for a blade server in this embodiment provides optimized adaptation for the multiple blade nodes of the blade server. By monitoring the power consumption of each blade node and the liquid cooling module through the overall management and control module and distributing the power consumption evenly among multiple power supply units, the system achieves balanced power consumption among the power supply units, enhancing the stability and reliability of the blade server, and improving the adaptability and control capabilities of the cold plate liquid cooling and multi-node systems.

In some embodiments, the overall management and control module 105 obtains a first power consumption by acquiring the current and voltage values of each blade node 101.

In some embodiments, an input end of the liquid cooling module 103 is provided with a first current sensor and a first voltage sensor. The overall management and control module 105 obtains a second power consumption according to data collected by the first current sensor and the first voltage sensor.

In some instances, the overall management and control module 105 is also configured for obtaining a third power consumption thereof during operations and a fourth power consumption of peripheral components of the blade server during operations.

In this embodiment, peripheral components refer to components shared by the blade nodes 101 in the blade server, in addition to the liquid cooling module 103 and the overall management and control module 105 mentioned above. For example, peripheral components can include hard drives, backplanes, and fans shared by multiple blade nodes 101. Accordingly, the fourth power consumption refers to the total power consumption of these hard drives, backplanes, and fans.

In some embodiments, the overall management and control module 105 is further configured for:
calculating a sum of all the first power consumption, the second power consumption, the third power consumption, and the fourth power consumption to obtain a total power consumption;
using a ratio of the total power consumption to a number of power supply units currently in operation as an output power consumption of each power supply unit.

In some embodiments, the overall management and control module 105 is also configured for:
recalculating the total power consumption and the output power consumption of each power supply unit in response to detecting an increase in the first power consumption of a certain blade node 101.

In this embodiment, at the moment when a single blade node experiences a sudden traffic surge, timely power consumption balancing intervention is carried out to achieve current sharing, and to ensure data reliability during the server's business operations, as well as the reliability and lifespan of the server itself.

In some embodiments, the overall management and control module 105 is also configured for:
in response to detecting an increase in the first power consumption of the certain blade node 101, proportionally increasing the second power consumption of the liquid cooling module 103 based on an increment of the first power consumption before recalculating the total power consumption and the output power consumption of each power supply unit.

In this embodiment, the liquid cooling module 103 can adjust accordingly according to the increase in power consumption of the blade node, promptly increasing the cooling demand, solving the problem of untimely heat dissipation in the server, and significantly improving the timeliness and efficiency of heat dissipation.

In some embodiments, the overall management and control module 105 is also configured for:
controlling the liquid cooling module 103 to increase a flow of coolant to the cold plate 102 corresponding to the certain blade node 101 based on the increment of the second power consumption of the liquid cooling module 103.

In this embodiment, in response to an increase in the power of a blade node, targeted rapid cooling for the corresponding blade node is performed, effectively avoiding local overheating or uneven heat dissipation among the server.

In some embodiments, the overall management and control module 105 is also configured for:
recalculating the total power consumption and the output power consumption of each power supply unit in response to detecting a decrease in the first power consumption of a certain blade node 101.

In this embodiment, at a moment when the traffic of a single blade node decreases, timely intervention is made to balance power consumption to achieve current sharing, avoiding resource waste, and ensuring data reliability during server operation, as well as the reliability and lifespan of the server itself.

In some embodiments, the overall management and control module 105 is also configured for:
in response to detecting a decrease in the first power consumption of a certain blade node 101, proportionally reducing the second power consumption of the liquid cooling module 103 based on the decrement of the first power consumption before recalculating the total power consumption and the output power consumption of each power supply unit.

In this embodiment, the liquid cooling module 103 can adjust accordingly according to the decrease in power consumption of the blade node, promptly reducing the cooling demand, avoiding resource waste, and improving cooling efficiency.

In some embodiments, the overall management and control module 105 is also configured for:
controlling, based on the decrement of the second power consumption of the liquid cooling module 103, the liquid cooling module 103 to reduce the flow of coolant to the cold plate 102 corresponding to the certain blade node 101.

In this embodiment, in response to a decrease in the power of a blade node, targeted reduction in the cooling capacity of the corresponding blade node is performed, avoiding uneven heat dissipation.

In some embodiments, the overall management and control module 105 is also configured for:
determining a coolant flow rate of the liquid cooling module according to the following formula:

$$μ = \frac{{\sum }_{n = 1}^{n} ( Pn ) + PL + PW + PC - {\sum }_{n = 1}^{n} ( PFn ) - σ}{ρ \cdot t \cdot Δ K \cdot c}$$

where represents the coolant flow rate, n represents the number of nodes, Pn represents the first power consumption, PL represents the second power consumption, PC represents the third power consumption, PW represents the fourth power consumption, PFn represents an useful work power consumption for actual operation of an n-th blade node, σ represents a heat dissipation loss of the liquid cooling module and the cold plates, ρ represents density of the coolant, t represents a preset regulation and monitoring time of the liquid cooling module, ΔK represents a temperature change of the coolant compared to the most recent regulation, c represents a specific heat capacity of the coolant;
adjusting the liquid cooling module to output coolant at the determined flow rate.

In some embodiments, the overall management and control module 105 is also configured for:
in response to a failure of a certain power supply unit, evenly distributing the total power consumption among remaining power supply units that have not failed.

In some embodiments, the multiple power supply units 104 adopt a redundant power supply architecture, which includes at least one backup power supply unit.

In some embodiments, the overall management and control module 105 is also configured for:
in response to the failure of a certain power supply unit, replacing the power supply unit that is faulty with the backup power supply unit and evenly distributing the total power consumption among the remaining power supply units and the backup power supply unit that is in operation.

In some embodiments, each blade node 101 includes a baseboard management controller, configured for obtaining the current and voltage values of the corresponding blade node 101 and send them to the overall management and control module 105.

In this embodiment, since each blade node usually has its own baseboard management controller, which inherently has the function of monitoring various components on the node, directly obtaining current and voltage data from the baseboard management controller avoids the need for separate modifications to the blade nodes. This allows the use of existing conventional blade servers, helping to save costs.

In some embodiments, each blade node 101 includes a second current sensor and a second voltage sensor. The overall management and control module 105 obtains the current and voltage values of the corresponding blade node 101 through the second current sensor and the second voltage sensor.

In this embodiment, to ensure the stability of power control, separate current and voltage sensors are provided for enhancing safety. Even when the baseboard management controller is not functioning properly or has not yet started normally, the overall power consumption can still achieve current sharing. Once the baseboard management controller is functioning properly, it switches to the accurate power consumption acquisition state of the corresponding blade node, ensuring good stability.

In some embodiments, the overall management and control module 105 is further configured for:
adjusting an output voltage and an output current of each of the power supply units to be the same, so that the power consumption is evenly distributed among the multiple power supply units 104.

In some embodiments, as shown in FIG. 2, this application also provides a power control method 200 for a blade server. Specifically, the method includes the following steps:
at step 201, obtaining a first power consumption of each blade node;
at step 202, obtaining a second power consumption of the liquid cooling module provides cooling for all blade nodes;
at step 203, obtaining a third power consumption of the overall management and control module during operations and a fourth power consumption of peripheral components of the blade server during operations;
at step 204, calculating a total power consumption based on the first power consumption, the second power consumption, the third power consumption, and the fourth power consumption;
at step 205, distributing the total power consumption among multiple power supply units evenly.

The power control method for a blade server in this embodiment provides optimized adaptation for the multi-blade node architecture of blade servers. By monitoring the power consumption of each blade node and the liquid cooling module through the overall management and control module and distributing the power consumption evenly among multiple power supply units, the method achieves balanced power consumption among the power supply units, enhancing the stability and reliability of the blade server, and improving the adaptability and control capabilities of the cold plate liquid cooling and multi-node systems.

In some embodiments, the method further includes:
in response to detecting an increase in the first power consumption corresponding to a certain blade node, returning to the step of obtaining the first power consumption of each blade node.

In some embodiments, the step of returning to obtain the first power consumption of each blade node further includes:
before returning to the step of obtaining the first power consumption of each blade node, proportionally increasing the second power consumption of the liquid cooling module based on the increment of the first power consumption.

In some embodiments, the step of proportionally increasing the second power consumption of the liquid cooling module based on the increment of the first power consumption further includes:
based on the increment of the second power consumption of the corresponding liquid cooling module, increasing the flow of coolant to the cold plate corresponding to a certain blade node through the liquid cooling module.

In some embodiments, the method further includes:

In response to detecting a decrease in the first power consumption of a certain blade node, returning to the step of obtaining the first power consumption of each blade node.

In some embodiments, the step of returning to obtain the first power consumption of each blade node further includes:
before returning to the step of obtaining the first power consumption of each blade node, proportionally decreasing the second power consumption of the corresponding liquid cooling module based on the decrement of the first power consumption.

In some embodiments, the step of proportionally decreasing the second power consumption of the corresponding liquid cooling module based on the decrement of the first power consumption further includes:
based on the decrement of the second power consumption of the corresponding liquid cooling module, reducing the flow of coolant to the cold plate corresponding to a certain blade node through the liquid cooling module.

In yet another embodiment, to facilitate understanding of the solution of this application, this embodiment takes a blade server including n blade nodes as an example to describe the solution of this application in detail. In a power control system for a blade server, the power input of the blade server is jointly supported by n PSUs. In addition, it may also involve modules commonly used among blades, such as hard drives, hard drive backplanes, fans, cold plates, and the overall management and control module. On the basis of the original air-cooled multi-node system, the overall management and control module realizes the heat dissipation control of the cold plates, including controlling the fluid replenishment and managing the coolant flow rate. The power supply of the liquid cooling module is also managed by the overall management and control module.

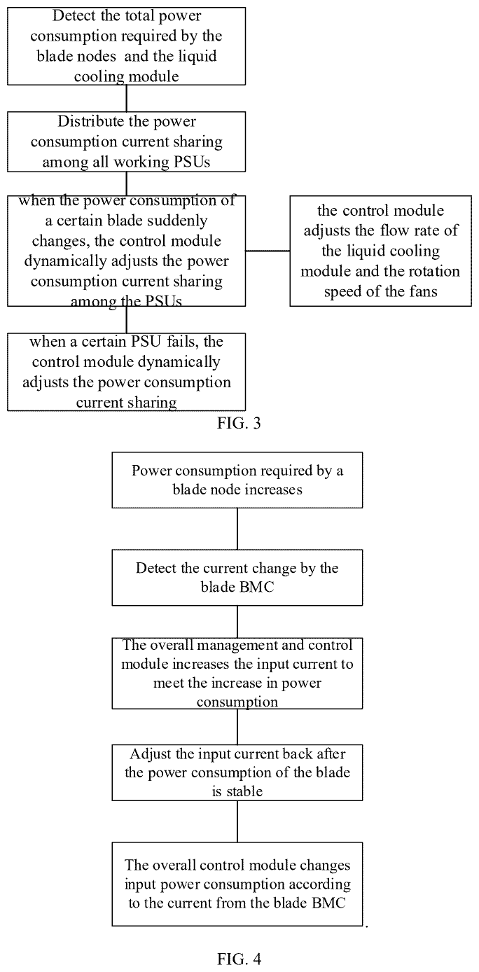

Referring to FIG. 3, the working principle of the overall management and control module is as follows. A multi-node blade server involves power supply from multiple PSUs, with each PSU being powered on separately. The PSUs are uniformly managed and controlled for power consumption balance by the overall management and control module. Under normal operating conditions of the server, the power on the PSUs needs to reach a balanced output to ensure the normal operation of the server. When a single node experiences a sudden traffic surge, power consumption balance intervention should be carried out in time to achieve current sharing, and to ensure the reliability of data during the business operation of the server, as well as the reliability and service life of the server's stable operation. To ensure the stability of business data, power redundancy is set, with redundancy ranging from N+1 to N+N. Here, N represents the number of PSUs required to support the normal operation of the system, and the following number represents the maximum number of PSUs that can malfunction. While ensuring the normal operation of the cold plate server and on the basis of ensuring the current sharing of the PSUs, the server system and the overall management and control module also need to support the redundant design of the server. The implementation method should not affect the power balance of the blade server. When the redundancy comes into effect, the overall management and control module needs to quickly complete the power re-balancing of multiple PSUs.

The specific functional implementation of the overall management and control module will be described in detail below.

In practical applications, the overall management and control module can be used to detect the total power consumption required by the blade nodes and the liquid cooling module.

Detecting the power consumption of the blade nodes is already a mature solution. Usually, the total power consumption of the nodes is calculated through the sensor on the BMC chip (Baseboard Management Controller) of each node itself, and the relevant data is transmitted to the overall management and control module through the signal line. This application needs to add the detection of the power consumption of the liquid cooling module. For the liquid cooling module, it only needs to achieve the function of cooling the coolant. Therefore, under standard conditions, only a temperature sensor needs to be equipped. To accurately determine its power consumption, a current sensor is added to the input end of the entire liquid cooling module. Since its power supply voltage is constant (usually set at 12V DC), the power consumption of the liquid cooling module can be calculated by the overall management and control module.

It should be noted that the above calculation method will result in relatively accurate power consumption, and the overall management and control module will also obtain the power consumption of each blade node and the liquid cooling module relatively accurately. When the BMC module of a node malfunctions or has not been started normally, the overall machine power consumption can be obtained through the total output current and the input voltage. Since the power output of the PSUs is realized through the overall management and control module, the overall management and control module can directly obtain the relevant power consumption data in this case. After the BMC starts to work normally, it will switch to the above state of accurately obtaining the power consumption of each blade.

In practical applications, the overall management and control module can also be used to distribute the power consumption current sharing among all working PSUs.

Usually, the output voltage and input voltage of each PSU are the same. In this case, to achieve balanced power consumption, only current balance needs to be achieved. After obtaining the value of the overall machine power consumption M, the overall management and control module obtains the total number N of currently available PSUs and distributes the current evenly among each PSU. At this time, the power consumption that each PSU needs to bear is: M/N, and the input current it needs to withstand is: (M/N)/the input voltage of the computer room. It should be noted that the input voltage of the computer room is determined according to the support of the PSUs and the actual situation of the computer room, and there are multiple possibilities such as 110V, 220V, and 380V.

In practical applications, when the power consumption of a certain blade suddenly changes, the overall management and control module can dynamically adjust the power consumption current sharing among the PSUs.

Due to the differences in the business flows running among the blades, there may be a situation where the power consumption of a certain blade node suddenly changes. A sudden decrease in power consumption has a relatively small impact on the overall machine, and the possibility of damage to the overall machine system is also small. However, when the power consumption of the overall machine system suddenly increases, if there is no intervention and control from the overall machine management module, it may cause the current of a single PSU to be too large, resulting in damage to the PSU or a crash of the entire system, which will greatly affect the deployment and use of the business. To avoid the above situation, the power consumption of the overall machine is controlled by the overall management and control module, and no longer by a single node using its corresponding PSU. That is, the power consumption resources of the PSUs are treated as a whole, which can be regarded as a power consumption pool, and the required power consumption values are all obtained from this power consumption pool.

Referring to FIG. 4, when the power consumption required by the components of a certain node suddenly increases, the current sensor of this node will detect the current change in the demand circuit in the first place. After this information is obtained by the Baseboard Management Controller (BMC), the BMC transmits the information that the current demand has increased back to the overall management and control module. Then, the overall management and control module starts to increase the power supply, that is, gradually increases the input current and distributes it evenly among the PSUs. However, such slow increase may still not meet the actual power consumption demand of the node with an increased power consumption demand. At this time, the current increase strategy needs to be adjusted according to the current increase value transmitted back by the BMC for the corresponding change in the overall machine input current. To ensure that the business of the overall machine does not stop or crash due to insufficient power consumption, the growth rate of the current needs to be slightly higher than the growth rate of the required power consumption. After the current grows to the required current value, it is then adjusted back.

In practical applications, the overall management and control module can adjust the flow rate of the liquid cooling module and the rotation speed of the fans.

When the power consumption of a blade node changes, the heat dissipation demand thereof also changes accordingly. At this time, the liquid cooling module synchronously increases the flow rate of the coolant or the rotation speed of the heat dissipation fans. In this process, to correspondingly increase or decrease the power supply, the current of the liquid cooling module needs to change synchronously. To achieve this goal and ensure that the liquid cooling module does not become a bottleneck for power consumption limitation when the required power consumption of the node increases, the current increased by the overall machine control and management module needs to cover both the power consumption required by the node and the power consumption required to drive the heat-dissipation work. In addition, the additional current margin also needs to cover the current required for the air-cooling and liquid-cooling heat dissipation regulation. After a round of regulation is completed, the current is synchronously adjusted back to an appropriate value to avoid power waste and the overall power consumption shortage caused by the need to increase the power consumption again due to excessive current supply, and to avoid abnormal subsequent regulation.

In practical applications, when a certain PSU fails, the overall management and control module dynamically adjusts the power consumption current sharing.

The implementation of power redundancy uses existing technologies. In addition to the power supply required by the server nodes, the power supply required by the liquid cooling module also needs to be considered.

The power control system for a blade server in this embodiment provides optimized adaptation for the multi-blade node architecture of blade servers, achieving balanced power consumption of the overall machine's PSUs. Moreover, power redundancy is implemented among the multi-node servers to ensure the high reliability and security of the server products.

In some embodiments, this application also provides a blade server. In addition to a standard chassis, hard drives, hard drive backplanes, fans, and network connection modules commonly used among multiple blade nodes, the blade server also includes the above power control system for a blade server. The system includes: multiple blade nodes; cold plates in thermal exchange with each blade node, with coolant inside the cold plates; a liquid cooling module for circulating the coolant in each cold plate; multiple power supply units for supplying power to the multiple blade nodes and the liquid cooling module; an overall management and control module, which is communicatively connected to each blade node, the liquid cooling module, and each power supply unit, for monitoring the power consumption of each blade node and the liquid cooling module and distributing the power consumption evenly among the multiple power supply units.

In some embodiments, the overall management and control module obtains the first power consumption by acquiring the current value and voltage value of each blade node.

In some embodiments, a first current sensor and a first voltage sensor are installed at the input end of the liquid cooling module. The overall management and control module obtains the second power consumption through the data collected by the first current sensor and the first voltage sensor.

In some embodiments, the overall management and control module is also used to obtain the third power consumption thereof during operations and the fourth power consumption of the peripheral components of the blade server during operations.

In some embodiments, the overall management and control module is further configured for calculating the sum of all the first power consumption, the second power consumption, the third power consumption, and the fourth power consumption to obtain the total power consumption, and uses the ratio of the total power consumption to the number of power supply units currently in operation as the output power consumption of each power supply unit.

In some embodiments, the overall management and control module is also configured for recalculating the total power consumption and the output power consumption of each power supply unit in response to detecting an increase in the first power consumption of a certain blade node.

In some embodiments, the overall management and control module is also configured for, in response to detecting an increase in the first power consumption of a certain blade node, proportionally increasing the second power consumption of the liquid cooling module based on the increment of the first power consumption before recalculating the total power consumption and the output power consumption of each power supply unit.

In some embodiments, the overall management and control module is also configured for controlling, based on the increment of the second power consumption of the liquid cooling module, the liquid cooling module to increase the flow of coolant to the cold plate corresponding to the certain blade node.

In some embodiments, the overall management and control module is also configured for recalculating the total power consumption and the output power consumption of each power supply unit in response to detecting a decrease in the first power consumption of a certain blade node.

In some embodiments, the overall management and control module is also configured for:

in response to detecting a decrease in the first power consumption of a certain blade node, proportionally decreasing the second power consumption of the liquid cooling module based on the decrement of the first power consumption before recalculating the total power consumption and the output power consumption of each power supply unit.

In some embodiments, the overall management and control module is also configured for:
controlling, based on the decrement of the second power consumption of the liquid cooling module, the liquid cooling module to reduce the flow of coolant to the cold plate corresponding to the certain blade node.

In some embodiments, the overall management and control module is also configured for:
determining a coolant flow rate of the liquid cooling module according to the following formula;

$$μ = \frac{{\sum }_{n = 1}^{n} ( Pn ) + PL + PW + PC - {\sum }_{n = 1}^{n} ( PFn ) - σ}{ρ \cdot t \cdot Δ K \cdot c}$$

where μ represents the coolant flow rate, n represents the number of nodes, Pn represents the first power consumption, PL represents the second power consumption, PC represents the third power consumption, PW represents the fourth power consumption, PFn represents an useful work power consumption for actual operation of an n-th blade node, σ represents a heat dissipation loss of the liquid cooling module and the cold plates, p represents density of the coolant, t represents a preset regulation and monitoring time of the liquid cooling module, ΔK represents a temperature change of the coolant compared to the most recent regulation, c represents a specific heat capacity of the coolant;
adjusting the liquid cooling module to output the coolant at the determined coolant flow rate.

In some embodiments, the overall management and control module is also configured for:
in response to the failure of a certain power supply unit, evenly distributing the total power consumption among the remaining power supply units that have not failed.

In some embodiments, the multiple power supply units adopt a redundant power supply architecture, where the redundant power supply architecture includes at least one backup power supply unit.

In some embodiments, the overall management and control module is also configured for:
in response to the failure of a certain power supply unit, replacing the faulty power supply unit with a backup power supply unit and evenly distributing the total power consumption among the remaining power supply units and the backup power supply unit in operation.

In some embodiments, each blade node includes a baseboard management controller, which is used to acquire the current value and voltage value of the corresponding blade node and send them to the overall management and control module.

In some embodiments, each blade node includes a second current sensor and a second voltage sensor. The overall management and control module acquires the current value and voltage value of the corresponding blade node through the second current sensor and the second voltage sensor.

In some embodiments, the overall management and control module is further configured for:
adjusting the output voltage and output current of each power supply unit to the same, thereby distributing the power consumption evenly among the multiple power supply units.

The technical features of the above embodiments can be combined arbitrarily. To make the description concise, all possible combinations of the various technical features in the above embodiments are not described. However, as long as there is no contradiction in the combination of these technical features, they should be considered within the scope described in this specification.

The above embodiments only represent several implementation modes of this application. The description is relatively specific and detailed, but it should not be understood as a limitation on the scope of the application. It should be noted that for those skilling in the art, several modifications and improvements can be made without departing from the concept of this application, and these all belong to the protection scope of this application. Therefore, the protection scope of the patent of this application shall be subject to the appended claims.

1. A power control system for a blade server, comprising:
multiple blade nodes;
cold plates in thermal exchange with the blade nodes, wherein the cold plates contain coolant;
a liquid cooling module for circulating the coolant in each of the cold plates;
multiple power supply units for supplying power to the multiple blade nodes and the liquid cooling module; and
an overall management and control module, communicatively connected to each of the blade nodes, the liquid cooling module, and each of the power supply units, configured for monitoring power consumption of each of the blade nodes and the liquid cooling module, and distributing the power consumption evenly among the multiple power supply units;
wherein the overall management and control module is configured for:
obtaining a first power consumption by acquiring a current value and a voltage value of each of the blade nodes;
obtaining a second power consumption according to data collected by a first current sensor and a first voltage sensor are provided at an input end of the liquid cooling module;
obtaining a third power consumption thereof during operations and a fourth power consumption of peripheral components of the blade server during operations;
calculating a sum of all the first power consumption, the second power consumption, the third power consumption, and the fourth power consumption to obtain a total power consumption; and
using a ratio of the total power consumption to a number of power supply units currently in operation as an output power consumption of each of the power supply units.

2-5. (canceled)

6. The power control system for the blade server according to claim 5, wherein the overall management and control module is further configured for:
recalculating the total power consumption and the output power consumption of each of the power supply units in response to detecting an increase in the first power consumption of a certain blade node.

7. The power control system for the blade server according to claim 6, wherein the overall management and control module is further configured for:
in response to detecting the increase in the first power consumption of the certain blade node, proportionally increasing the second power consumption of the liquid cooling module based on an increment of the first power consumption before recalculating the total power consumption and the output power consumption of each of the power supply units.

8. The power control system for the blade server according to claim 7, wherein the overall management and control module is further configured for:
controlling, based on the increment of the second power consumption of the liquid cooling module, the liquid cooling module to increase a flow of coolant to the cold plate corresponding to the certain blade node.

9. The power control system for the blade server according to claim 5, wherein the overall management and control module is further configured for:
recalculating the total power consumption and the output power consumption of each of the power supply units in response to detecting a decrease in the first power consumption of a certain blade node.

10. The power control system for the blade server according to claim 9, wherein the overall management and control module is further configured for:
in response to detecting the decrease in the first power consumption of the certain blade node, proportionally decreasing the second power consumption of the liquid cooling module based on a decrement of the first power consumption before recalculating the total power consumption and the output power consumption of each of the power supply units.

11. The power control system for the blade server according to claim 10, wherein the overall management and control module is further configured for:
controlling, based on the decrement of the second power consumption of the liquid cooling module, the liquid cooling module to reduce a flow of coolant to the cold plate corresponding to the certain blade node.

12. The power control system for the blade server according to claim 6, wherein the overall management and control module is further configured for:
determining a coolant flow rate of the liquid cooling module according to the following formula:
$$μ = \frac{{\sum }_{n = 1}^{n} ( Pn ) + PL + PW + PC - {\sum }_{n = 1}^{n} ( PFn ) - σ}{ρ \cdot t \cdot Δ K \cdot c}$$
wherein μ represents the coolant flow rate, n represents the number of nodes, Pn represents the first power consumption, PL represents the second power consumption, PC represents the third power consumption, PW represents the fourth power consumption, PFn represents an useful work power consumption for actual operation of an n-th blade node, σ represents a heat dissipation loss of the liquid cooling module and the cold plate, ρ represents density of the coolant, t represents a preset regulation and monitoring time of the liquid cooling module, AK represents a temperature change of the coolant compared to the most recent regulation, c represents a specific heat capacity of the coolant;
adjusting the liquid cooling module to output the coolant at the determined coolant flow rate.

13. The power control system for the blade server according to claim 5, wherein the overall management and control module is further configured for:
in response to a failure of a certain power supply unit, distributing the total power consumption evenly among remaining power supply units that have not failed.

14. The power control system for the blade server according to claim 5, wherein the multiple power supply units adopt a redundant power supply architecture, and the redundant power supply architecture comprises at least one backup power supply unit;
wherein the overall management and control module is further configured for:
in response to the failure of a certain power supply unit, replacing the power supply unit that is faulty with the backup power supply unit and distributing the total power consumption evenly among the remaining power supply units and the backup power supply unit that is in operation.

15. (canceled)

16. The power control system for the blade server according to claim 2, wherein each of the blade nodes comprises a baseboard management controller, configured for acquiring a current value and a voltage value of the corresponding blade node and sending them to the overall management and control module; or
wherein each of the blade nodes comprises a second current sensor and a second voltage sensor, and the overall management and control module acquires the current value and voltage value of the corresponding blade node through the second current sensor and the second voltage sensor.

17. (canceled)

18. The power control system for the blade server according to claim 1, wherein the overall management and control module is further configured for:
adjusting an output voltage and an output current of each of the power supply units to be the same, so that the power consumption is evenly distributed among the multiple power supply units.

19. A power control method for a blade server, comprising:
acquiring a first power consumption of each blade node;
acquiring a second power consumption of a liquid cooling module providing cooling for all blade nodes;
acquiring a third power consumption of an overall management and control module during operations and a fourth power consumption of peripheral components of the blade server during operations;
calculating a total power consumption based on the first power consumption, the second power consumption, the third power consumption, and the fourth power consumption; and
distributing the total power consumption among multiple power supply units evenly.

20. The power control method for the blade server according to claim 19, further comprising:
returning to the step of acquiring the first power consumption of each blade node in response to detecting an increase in the first power consumption of a certain blade node.

21. The power control method for the blade server according to claim 20, wherein before returning to the step of acquiring the first power consumption of each blade node, the method further comprises:
proportionally increasing the second power consumption of the liquid cooling module based on an increment of the first power consumption.

22. The power control method for the blade server according to claim 21, wherein the step of proportionally increasing the second power consumption of the liquid cooling module based on the increment of the first power consumption further comprises:
increasing, based on the increment of the second power consumption of the liquid cooling module, a flow of coolant to the cold plate corresponding to the certain blade node through the liquid cooling module.

23. The power control method for the blade server according to claim 19, further comprising:
returning to the step of acquiring the first power consumption of each blade node in response to detecting a decrease in the first power consumption of a certain blade node.

24. The power control method for the blade server according to claim 23, wherein before returning to the step of acquiring the first power consumption of each blade node, the method further comprises:
proportionally decreasing the second power consumption of the liquid cooling module based on a decrement of the first power consumption.

25. The power control method for the blade server according to claim 24, wherein the step of proportionally decreasing the second power consumption of the liquid cooling module based on the decrement of the first power consumption further comprises:
reducing, based on the decrement of the second power consumption of the liquid cooling module, a flow of coolant to the cold plate corresponding to the certain blade node through the liquid cooling module.

26. A blade server comprising a power control system, wherein the power control system comprises:
multiple blade nodes;
cold plates in thermal exchange with the blade nodes, wherein the cold plates contain coolant;
a liquid cooling module for circulating the coolant in each of the cold plates;
multiple power supply units for supplying power to the multiple blade nodes and the liquid cooling module; and
an overall management and control module, communicatively connected to each of the blade nodes, the liquid cooling module, and each of the power supply units, configured for monitoring power consumption of each of the blade nodes and the liquid cooling module, and distributing the power consumption evenly among the multiple power supply units;
wherein the overall management and control module is configured for:
obtaining a first power consumption by acquiring a current value and a voltage value of each of the blade nodes;
obtaining a second power consumption according to data collected by a first current sensor and a first voltage sensor are provided at an input end of the liquid cooling module;
obtaining a third power consumption thereof during operations and a fourth power consumption of peripheral components of the blade server during operations;
calculating a sum of all the first power consumption, the second power consumption, the third power consumption, and the fourth power consumption to obtain a total power consumption; and
using a ratio of the total power consumption to a number of power supply units currently in operation as an output power consumption of each of the power supply units.
